(19) United States
(12) Patent Application Publication
(10) Pub. No.: US 2009/0022243 A1
(43) Pub. Date: Jan. 22, 2009

(54) METHOD FOR DATA TRANSMISSION, TRANSMITTER STATION AND COMMUNICATION SYSTEM

(75) Inventors: Paul Walter Baier, Kaiserslautern (DE); Jochen Hahn, Kaiserslautern (DE); Faruk Keskin, Ludwigshafen (DE); Wolfgang Zirwas, Munich (DE)

Correspondence Address: STAAS & HALSEY LLP, SUITE 700, 1201 NEW YORK AVENUE, N.W., WASHINGTON, DC, 20005, US

(73) Assignee: Siemens Aktiengesellschaft, Munich (DE)

(21) Appl. No.: 11/780,787

(22) Filed: Jul. 20, 2007

(51) Int. Cl. H03C 3/00; H04L 27/12

(52) U.S. Cl. 375/302

(57) ABSTRACT

The present invention is related to a method for data transmission between a transmitter station and a receiver station of a communication system, especially a wireless communication system, employing a transmission scheme based on the principle of receiver orientation, wherein for the generation of low energy transmit signals within the transmitter station expanded landings on multiple representatives of the complex plane are used and wherein each one of the expanded landing is arranged within an expanded domain of the complex plane. The present invention further relates to a transmitter station and a communication system.

### FIELD OF THE INVENTION

The present invention is related to a method for data transmission between a transmitter station and a receiver station of a communication system, especially a wireless communication system. The present invention further relates to a transmitter station and a communication system.

### TECHNICAL BACKGROUND OF THE INVENTION

Wireless communication systems—also known as radio communication systems—are well-known in the art. A wireless communication system refers to a communication system having a transmitting end and a receiving end in which signals are transmitted or communicated from the transmitting end to the receiving end via a signal path, wherein a portion of this signal path from the transmitting end to the receiving end includes signal transmission via a wireless interface. Therefore, in wireless communication systems, data (for example voice data, image data or other digital data) is transmitted by means of electro-magnetic waves via a wireless interface. This wireless interface is also known as radio interface.

The present application is addressed to the problem of reducing the transmitting power within a downlink of a communication system and thus to reduce the transmitting power within a base station. Also, low transmitting power is desirable with respect to diminishing the electromagnetic irradiations as a possible source of health hazards and to the mitigation of interference to other radio links.

Conventional transmission schemes can be classified as transmitter oriented or receiver oriented:

In conventional transmitter oriented transmission schemes, the receiver algorithms a priori are given and made known to the receiver, whereas the transmitter algorithms to be used by the receiver have to be a posteriori adapted correspondingly, possibly under consideration of certain channel information.

In contrast to the transmitter oriented transmission a basic advantage of the principle of receiver orientation is the fact that the a priori chosen receiver algorithms can be used with a view to arrive at simpler receiver structures. The principle of the receiver orientation is described, for example, in M. Meurer, P. W. Baier, and W. Qiu, “Receiver Orientation versus Transmitter Orientation in Linear MIMO Transmission Systems”, EURASIP Journal on Applied Signal Processing, vol. 9, pp. 1191-1198, 2004.

The present application is further addressed especially to radio communication systems operating on the principle of the receiver orientation. Those radio communication systems are especially preferable in the downlink of a multi-user mobile communication system.

Hereinafter, the present invention and its underlying problem are therefore described with regard to the downlink of a radio communication system operating on the principle of receiver orientation, whereas it should be noted that the present application is not restricted to this kind of communication systems but can also be used for other kinds of communication systems operating in a different manner.

Using receiver oriented transmission schemes there are several concepts for the reduction of the transmitting power:

In the transmit zero-forcing transmission scheme or shortly TxZF transmission scheme, single that is unique discrete valued representatives of the data elements are chosen in the complex plane. These single representatives are aimed at the sense of spot landings by designing the transmit signals correspondingly. With TxZF it is possible to implement a comparably low-cost receiver.

Another concept is the transmit non-linear zero-forcing transmission scheme or shortly TxNZF, which is, for example, described in M. Meurer, T. Weber, and W. Qiu, “Transmit Nonlinear Zero Forcing: Energy Efficient Receiver Oriented Transmission in MIMO CDMA Mobile Radio Downlinks”, in Proc. IEEE 8th International Symposium on Spread Spectrum Techniques & Applications (ISSSTA'04), Sydney, 2004, pp. 260-269 or in the European Patent Application EP 1 538 774 A1. TxNZF is an extended version of TxZF with the special view to diminish the required transmitting power under maintaining the low complexity of the mobile terminals. In contrast to TxZF, in TxNZF discrete valued multiple representatives of the data elements are used and placed in the complex plane, which again aimed at the sense of spot landings.

By using multiple representatives with TxNZF that is by selectable data representation it is possible to choose for the same data between different transmitting signals. By choosing the transmitting signal having the lowest energy, it is then possible to reduce the transmitting energy. However, this choice is restricted due to the concept of using spot landings for the different discrete valued representatives.

The present invention, therefore, is based on the object to reduce the transmitting power especially for the downlink communication using receiver oriented transmission schemes.

### SUMMARY OF THE INVENTION

In accordance with the present invention, a method having the features of claim 1 and/or a transmitter station having the features of claim 26 and/or a communication system having the features of claim 27 is/are provided.

Accordingly, it is provided:

A method for data transmission between at least one transmitter station and at least one receiver station of a communication system, especially a wireless communication system, employing a transmission scheme based on the principle of receiver orientation, wherein for the purpose of selectable data representation the transmit signals comprises the transmit data elements and wherein the transmit data elements are represented by continuous valued representative domains in the complex plane, comprising: generating the transmit signals within the transmitter station by optimization such that in the receiver stations extended continuous valued landings on the continuous valued representative domains occur.

A transmitter station for data transmission using a receiver station of a communication system capable to perform a method according to the present invention.

A communication system, especially a radio communication system, comprising at least one transmitter station and at least one receiver station capable to establish a communication with each other via an interface, especially a radio interface, wherein at least one of the transmitter stations is a transmitter station according to the present invention.

The present invention employs an approach based on the receiver orientation principle. This approach hereinafter is referred to as “Minimum Energy Soft Precoding” or shortly MESP. This term was chosen since it is assumed to be suggestive to denote the flexible selectable landings which are arranged somewhere in discrete valued domains as “soft”-landings whereas the inflexible landings on discrete spots are in contrast to this denoted as “hard”-landings. This MESP concept is based on the conventional TxZF and TxNZF concepts, respectively, in that sense that the basic principles of spot landings on single discrete valued (TxZF) or multiple discrete valued (TxNZF) representatives, respectively, are abandoned in favour of landings in more or less extended continuous valued domains of the complex plane. These extended domains of the complex plane are referred to as representative domains or representative regions.

The underlying idea of the present patent application is the employment of continuous valued representative domains for the data transmission instead of conventional discrete valued domains. It was further realized, that this idea opens additional degrees of freedom in the generation of the transmit signal not only for the reduction of the transmitting power, but also for the realization of other preferable and desirable effects, such as an additional rest-factor reduction of the transmit signal, lower dynamics of the amplitude of the received signal. By an additional rest-factor reduction is possible to reduce the requirement on the linearity of the amplifier within the transmitting station. By reducing the dynamics of the amplitude of the received signal it is possible to also reduce the bandwidth requirements of the AD-converter on the side of the receiving station.

This MESP approach, according to the present invention, opens—compared to the above mentioned known approaches of TxZF and TxNZF utilizing spot landings—additional degrees of freedom when designing the transmit signals. The main benefit of using the new MESP approach is the fact that these degrees of freedom can be now advantageously exploited to arrive at transmit signals having energies which are lower than the energies of the transmit signals in the case of the known TxZF approach and the known TxNZF approach, respectively.

Another major benefit is the fact that the MESP according to the present invention approach can be also implemented in a very low-cost manner which is based on a step-wise approach.

Advantages, embodiments and further developments of the present invention can be found in the further subclaims and in the following description, referring to the drawings.

In a preferred embodiment of the invention the transmit data to be transmitted from the transmitter station to the receiver station comprises data elements having multiple continuous valued representatives in the complex plane, which are aimed at in the receivers stations during data transmission.

In a preferred embodiment of the invention a receiver orientation refers to a transmission scheme where the receiver forms the master and the transmitter station forms the slave of the data communication.

In a preferred embodiment of the invention the receiver algorithms are a priori given and made known to the transmitter station and wherein the transmitter algorithms are a posteriori adapted accordingly, especially under consideration of given channel state information.

In a preferred embodiment of the invention a channel is defined between the transmit antenna of the transmitter station and the reception antenna of the receiver station, wherein the channel state information of this channel is made available by a channel estimator in the transmitter station.

In a preferred embodiment of the invention an expanded continuous valued domain defines a region around at least one discrete valued representative.

In a preferred embodiment of the invention the expanded continuous valued domain is chosen in such a way that a symbol error probability for landings on the boundaries of this expanded domain is minimal.

In a preferred embodiment of the invention for determining the transmit vector of the transmit signal having a minimal transmit energy an exhaustive search, a quadratic solvers for constraint optimisation and/or a stepwise determination of the transmit vector is applied.

In a preferred embodiment of the invention the method is used in the downlink of a data communication.

In a preferred embodiment of the invention for data transmission Orthogonal Frequency Division Multiplex (OFDM) is applied to send the transmit signal.

In a preferred embodiment of the invention the method is applied to a MIMO communication system.

In a preferred embodiment of the invention the data transmission is symbol-based using at least one data symbol for transmitting the data.

In a preferred embodiment of the invention the communication system is a radio communication system and the interface between the transmitter station and the receiver station is a wireless interface.

In a preferred embodiment of the invention the method is applicable for 3G LTE, WIMAX and/or 4G communication systems.

In a preferred embodiment of the invention the data elements of the data vector are processed within the transmitter station in the order of increasing k_{R}. wherein k_{R} denotes the number of a specific data element of the data vector.

In a preferred embodiment of the invention for data transmission a data element specific transmit vector is generated.

In a preferred embodiment of the invention the data element specific transmit vector produces no interference to the elements of the complex data response vector.

### BRIEF DESCRIPTION OF THE DRAWINGS

For a more complete understanding of the present invention and advantages thereof, reference is now made to the following description taken in conjunction with the accompanying drawings. The invention is explained in more detail below using exemplary embodiments which are specified in the schematic figures of the drawings, in which:

FIG. 1 shows a model of a data transmission system;

FIG. 2 shows an example of different representatives D_{M}, P;

FIG. 3 shows a diagram of an embodiment of a radio communication system according to the present invention;

FIG. 4 shows a section of the example of FIG. 2 with representative domains generated and used according to the present invention;

FIG. 5 shows an example of a downlink communication of an OFDM data transmission system;

FIG. 6 shows a generic MIMO-OFDM downlink model for one single subcarrier;

FIG. 7 shows another example of representative domains generated and used according to the present invention;

FIG. 8A, 8B show curves characterizing the performance of the commonly known TxZF-approach and the MESP-approach according to the present invention;

FIG. 9 shows a procedure to calculate the vector t represented by a Nassi-Shneiderman diagram;

FIG. 10 shows various simulation results by using the TxZF-method, the TxNZF-method and the MESP-method according to the present invention.

In all figures of the drawings elements, features and signals which are the same or at least have the same functionality have been provided with the same reference symbols, unless explicitly stated otherwise.

### DETAILED DESCRIPTION OF PREFERRED EMBODIMENTS OF THE PRESENT INVENTION

In the following description of the present invention, a (wireless) radio communication system is described in which OFDM (orthogonal frequency division multiplexing) is used for sending send vectors, however, without restricting the present invention to this type transmission.

First of all, the basic principle of a known data transmission system and the corresponding data transmission method is described in order to characterise then the modified data transmission according to the present invention, which is, as already outlined above, a modification of these known transmission models is therefore based on these.

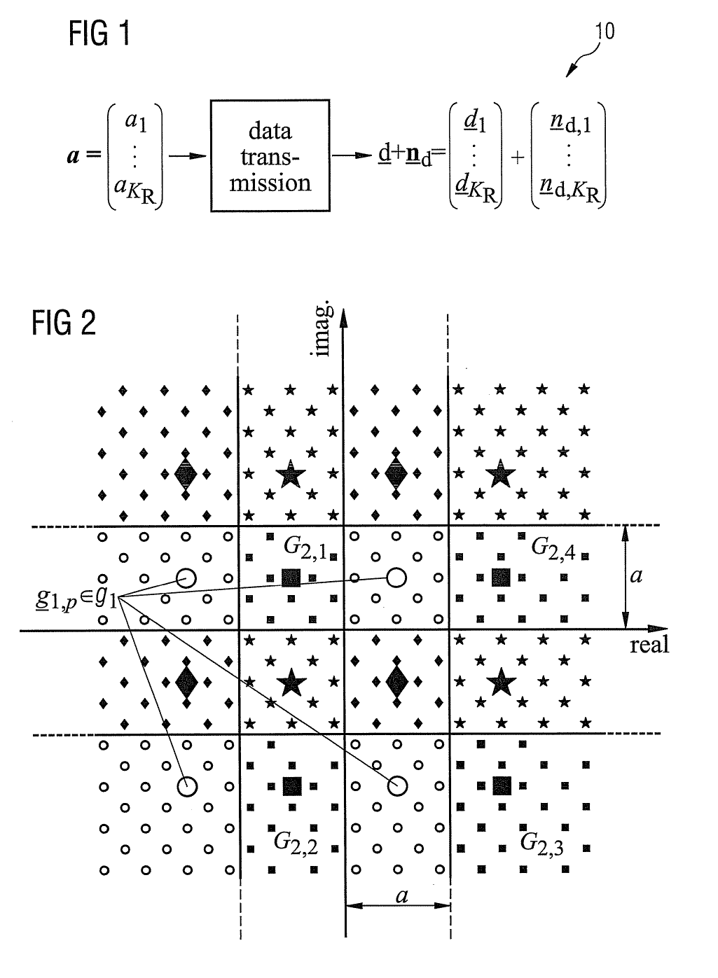

FIG. 1 shows a generic model which can be used for nearly all digital data transmission systems. This model is denoted by reference symbol 10. At the input side of the model 10 a data block

a=(a₁. . . a_{KR}) (1)

having K_{R} data elements a_{KR} with k_{R}=1 . . . K_{R} is provided. These data elements are taken from a data element set

G={G₁ . . . G_{M}} (2)

of cardinality M, that is each element of the data block a of equation of equation (1) can be taken on M different realizations. Then, in total

R=M^{K}^{_{R}} (3)

different realizations of the data block a of equation (1) exist. The elements a_{KR} of a of equation (1) can be considered to be non-physical information objects. At the output side of the model 10 the complex vector

d=(d₁ . . . d_{K}_{_{R}})^{T}, (4)

which is provided is the desired response of the model 10. Typically this vector d is corrupted by the complex random noise vector

n_{d}=(n_{d,1} . . . n_{d,k}_{_{R}})^{T} (5)

The elements d_{K}_{_{R}} of d of equation (4) and n_{d,k}_{_{R}} of n_{d} of equation (5) are physical signal quantities as for instance complex signal samples. The noise vector n_{d} of equation (5) can be characterised by the joint probability density function of its K_{R} components n_{d,K}_{_{R}} with k_{R}=1 . . . K_{R}.

Typically, a component-wise assignment of the components d_{K}_{_{R}} of d of equation (4) to the elements a_{KR} of a of equation (1) is provided. This means that if a_{KR} is based on a certain realization of Gₘ then the system model outputs d_{K}_{_{R}} whereas d_{K}_{_{R}} denotes (in the sense of a spot landing) one of the P values of the discrete complex set

gₘ={g_{m,1} . . . g_{m,P}}. (6)

Hereinafter, the different elements g_{m,1} . . . g_{m,P} of gₘ denote the representatives of Gₘ. Typically, but not necessarily, P is chosen equal to one.

However, more recently transmission schemes utilising THP or similar concepts, if met considerable interest, which imply values of P>1 until T≅∞. To each of the MP representatives g_{m,P} a decision reach or a Voronoi-Region (VR) G_{m,P} can be assigned. g_{m,P} lies somehow “centered” in its Voronoi-Region g_{m,P} and the amount of MP of the Voronoi-Regions completely tile the complex plane. The union

$${G}_{m} = {⋃}_{p = 1}^{p} {G}_{m , p} \qquad ( 7 )$$

of the P Voronoi Regions (VR) G_{m,p}, p=1 . . . P, is denoted as the total decision region of Gₘ.

The above mentioned component-wise assignment a_{KR}→dₖ_{_{R}} can be mathematically formulated as follows:

If aₖ_{_{R}}=Gₘ, then dₖ_{_{R}} εgₘ·. (8)

FIG. 2 shows one example of how the different representatives g_{m,p} of equation (6) can be positioned in the complex plane. In this example the following parameter settings are used:

M=4 (9)

and

P=4. (10)

Here, the representatives g_{m,p} are arranged in a grid of squares with the grid width a.

If the noise vector n_{d} of equation (5) is non-zero (n_{d}≠0), it may hamper spot landings on the representatives g_{m,p}. As a consequence of this detection errors may occur. If a_{KR} has the realization Gₘ, then the error probability of the transmission of a_{KR} can be expressed as (with Gₘ of equation (7)):

Pₐ_{_{kR}}=Prob(dₖ_{_{R}}+n_{d,k}_{_{R}}∉Gₘ|aₖ_{_{R}}=Gₘ). (11)

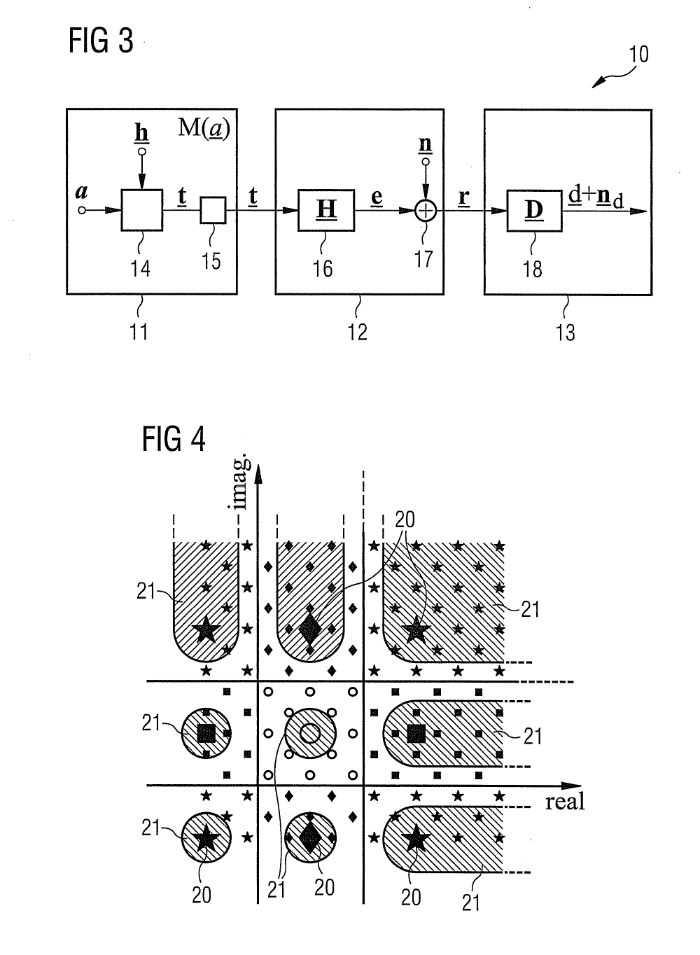

The generic model of FIG. 1 mediates between the non-physical world of information and the physical world of complex signal values. In what follows, it has to be concretely elaborated how this mediation takes place in practice. To this purpose the generic model of FIG. 1 is itemized in FIG. 3 into the different components transmitter, channel and receiver of a transmission system.

FIG. 3 shows one example of a schematic diagram of the radio communication system having a sending station, a transmission channel and a receiving station.

In FIG. 3, the communication system is denoted again by reference symbol 10. It is assumed that this communication system 10 is a wireless communication system. The communication system 10 comprises a base station 11, a channel 12 and a user equipment 13. In FIG. 3, the downlink of the communication system 10 is shown. The base station 11 features all devices which are required for operation of a base station in the communication system 10. For reasons of clarity, none of these devices except for an error correction coding unit 14 and a sending unit 15 are shown in FIG. 3. In the base station 11, a data vector a is used to be transmitted. This data vector a to be transmitted is routed to the error protection coding unit 14. Further, the error correction coding unit 14 is supplied with general coding information h, from which the channel states of at least those carrier frequencies can be taken, on which subsequently a send vector t formed by the base station 11 by error correction coding of the data vector a will be sent by the sending unit 15 to the user equipment 13. For example, each element of the send vector t is sent on an OFDM-subcarrier in each case.

The sending vector t contains Q elements and is formed from the data vector a to be sent taking into consideration the channel state information h=(h₁ . . . h_{Q})^{T} as well as taking into account the number of errors able to be corrected in the error correction coding unit 14 by the error correction code used. The error correction code used is, for example a block code, a convolutional code, a turbo code, a space time code, etc. Furthermore, the use of coded modulation is possible, which means that the enlargement of the band width necessary by increasing the modulation alphabet is bypassed, with the attempt always being made to achieve the maximum spacing between the individual code words.

For a data vector of the length N with binary values, there are 2^{N} different data vectors which can be formed and transmitted. The user equipment 13 does not know which data vector a the base station 11 is sending. However, the system involved is what is known as a receiver oriented system in which the user equipment 13 for each transmissible data vector a knows precisely one coded vector t₀.

The sending vector t is transmitted over the channel 12 indicated symbolically by a box in FIG. 3. In the transmission, a multiplication of the elements of the sending vector t by the elements of the general state information H is undertaken mathematically component by component in relation to OFDM. This scalar multiplication is done by the block 16 in the channel box 12. In this way, a vector e is produced to which the noise vector n typically present in the relevant wireless transmission channel is added component by component in the unit 17.

In the embodiment of FIG. 3, a separate carrier frequency, also referred to as separate subcarrier is used for sending the send vector t for each element. Thus, a separate transmission channel 12 with channel state information exists for each element. Of course, the same carrier frequency and thereby the same transmission channel 12 can be used for individual elements or for all elements.

After transmission over the channel 12, the user equipment 13 receives a receive vector r. The receive vector r is the sum of the vectors e and n.

The receive vector r is fed into the user equipment 13. The user equipment 13 is mainly described by the demodulator matrix 18, which at its output side finally provides the vectors d+n_{d}.

Hereinafter, the transmission model shown in FIG. 3 is described mathematically in more detail.

The transmitter 11 which forms the base station 11 in FIG. 3 is described mainly by the modulator operator M(a), which assigns a transmit vector t to the message block a of equation (1):

t=M(a) (12)

The transmit vector t of equation (12) is fed into the channel which is ideally characterized by the channel matrix H. This generates the useful receive vector e. by scalar multiplication of the channel matrix H and the transmit vector t.

e=H·t. (13)

e is then corrupted by the received noise vector n which is typically present in a wireless channel 12 to provide the disturbed receive vector r at the output side of the channel 12:

r=e+n. (14)

r of equation (14) is then fed into the receiver 13. This receiver 13 forms the user equipment 13 in FIG. 3 and is typically a mobile phone. The receiver 13 is described by the demodulator matrix D. The receiver 13 finally yields at an output side the data vector (d+n_{d}):

$$\begin{matrix}\underline{d} + {\underline{n}}_{d} = \underline{D} \cdot \underline{r} \\ = \underline{D} \cdot ( \underline{H} \cdot \underline{t} + \underline{n} ) \\ = \underline{D} \cdot ( \underline{H} \cdot M ( a ) + \underline{n} ) \\ = \underbrace{\underline{D} \cdot \underline{H} \cdot M ( a )} + \underbrace{\underline{D} \cdot \underline{n}}_{{\underline{n}}_{d}}\end{matrix} \qquad ( 15 )$$

d+n_{d} of equation (15) already occurred in the context of the generic model in FIG. 1. For given statistics of the noise vector n, the statistics of n_{d} depends on the choice of the demodulator matrix D. For instance, even if the components of the noise vector n are uncorrelated, the components of n_{d} of equation (15) may be correlated.

In the last years the above described receiver oriented concepts have gained considerable interest. This is especially true with respect to the downlinks of a communication system, because in such applications a low complexity of the mobile terminals (user equipments) is of very big importance.

In the light of the above mentioned considerations and in view of the transmission model shown in FIG. 3, the receiver orient concept is performed as follows:
1. The demodulator matrix D of the receiver 13 is given a priori.
2. The data vector d at the output side of the receiver 13 is chosen in accordance with the realization of the data block a of equation (1) to be transmitted (see equation (8)) where, in the case P>1, for each realization of the data block a P^{K} different vectors d can be chosen.
3. Setting out from the knowledge of the demodulator matrix D, the data vector d and the channel matrix H, finally (i.e. a posteriori) the vector t to be transmitted, or, equivalently, the modulator operator M(a) are decided.

Mathematically, the above described step 3, that is the generation of the transmit vector t such that the desired spot landings occur, can be formulated (under consideration of equation (9)) as:

t=M(a)=(DH)^{H}[DH(DH)^{H}⁻¹d. (16)

This algorithm (16) is also known as Transmit Zero Forcing (TxZF) algorithm.

The transmit vectors t of equation (12), (16) comprise the transmit energy

$$T = \frac{1}{2} {\underline{t}}^{H} \underline{t} . \qquad ( 17 )$$

If the transmit vector t is determined in the sense of the receiver orientation according to equation (16), then for a given setting of a, H, D and d, the transmit energy T of equation (17) reaches its minimum possible value. As stated above, in the case P>1 for each a from a selection of p^{KR} different data vectors d can be chosen, each entailing a different transmit vector t and, consequently, a different transmit energy T. This possibility to choose (in the case of P>1) enables the transmission of each data block with the lowest possible transmit energy T. Mathematically, this commonly known method can be formulated as:

$$\underline{t} = arg \{ {min}_{( {\underline{t}}^{′} ∈ {C}^{{K}_{T}} )} ( {\underline{{t}^{′}}}^{H} \underline{{t}^{′}} ) \} \\ \underline{DHt} = \underline{d} ⋀ ( {\underline{d}}_{{K}_{R}} ∈ {g}_{m} \vert {a}_{{K}_{R}} = {G}_{m} ) , ∀ {k}_{R} = 1 … {K}_{R ,} \qquad ( 18 )$$

The generation of the transmit vector t according to this equation (18) is also known as Transmit Non-linear Zero Forcing (TxNZF).

With these known transmission schemes, that is with the TxZF and TxNZF transmission schemes, it is possible to reduce the energy of a transmission to a great extend. However, as it is already stated above, it is a constant need to further reduce the required transmit energy T. Therefore, hereinafter, a concept for a further reduction of the required transmit energy T is described by mainly giving up the above mentioned concept of using spot-landings.

In order to illustrate this idea, reference is now made to FIG. 4 which shows a section the complex plane of FIG. 2. Instead of insisting on the known concept of using only spot landings 20 on the representatives g_{m,P,} now landings in the shaded domains 21 FIG. 4 are used whereas these shaded domains 21 define regions

G_{m,P}⊂G_{m,P} (19)

around each representative g_{m,P}. These landings are hereinafter denoted as representative domains 21. It has been turned out that it is not at all necessary to use exact spot landings. It has been further turned out that these representative domains 21 are also sufficient compared to the spot landings. The union

$${\tilde{G}}_{m} = {⋃}_{p = 1}^{P} {\tilde{G}}_{m , p} \qquad ( 20 )$$

of the P representative domains G_{m,P,} (with p=1 . . . P) is denoted as total representative domain Gₘ. The representative domains G_{m,P} can be chosen in such a way that the symbol error probabilities P_{αkR} for landings on the boundaries of the representative domain Gₘ attain pre-set values P₀,_{αkR}, and are below these values for landings within the representative domain Gₘ. Then, mathematically, the representative domains G_{m,P} are given by

G_{m,P}={dₖ_{_{R}} εG_{m,P}|Prob(dₖ_{_{R}}+n_{d,k}_{_{R}}εG_{m,P}|aₖ_{_{R}}=Gₘ)}≧1−P_{0,a}_{_{kR}}. (21)

The establishment of the representative domains G_{m,P} according to equation (21) for given values P_{0,a}_{_{kR}} mainly depends on the statistics of n_{d} of equation (15).

To use now representative domains G_{m,P} instead of only single spot representatives g_{m,P} as proposed above opens a new degree of freedom, especially when determining the transmit vector t for a given realization of the data block a of equation (1). Further this increases the chances to identify transmit vectors t with energies lower than those of the transmit vectors t gained according to known methods and concepts as described above and as given by equation (18). Mathematically, this minimization of the transmit energy can be written as

$$\underline{t} = arg \{ {min}_{( {\underline{t}}^{′} ∈ {C}^{{K}_{T}} )} ( {\underline{{t}^{′}}}^{H} \underline{{t}^{′}} ) \} \\ \underline{DHt} = \underline{d} ⋀ ( {\underline{d}}_{{K}_{R}} ∈ {\tilde{G}}_{m} \vert {a}_{{K}_{R}} = {G}_{m} ) , ∀ {k}_{R} = 1 … {K}_{R ,} \qquad ( 22 )$$

This new approach of minimizing the transmit energy according to equation (22) is denoted as Minimum Energy Receiver Orientation or shortly as MESP. For performing MESP, that is for determining the transmit vector t of equation (22) having a minimal transmit energy, a large number of possibilities exists.

Some of these possibilities are hereinafter described in more detail.

Exhaustive Search:
This method would be the straight-forward method, however, which might be a little bit more expensive than other methods.

Quadratic Solvers for Constraint Optimisation:
As compared to the above mentioned exhaustive search, this can be considered to be a more systematic and less expensive way to arrive at the optimum solution.

Stepwise Determination of the Transmit Vector t:
This method is the least expensive one, however, at the prize of possibly not reaching the transmit signal t having the optimal minimum energy.

Hereinafter, an illustrative example of the MESP multi-user MIMO (MIMO =multi-input multi-output) OFDM downlink is described:

Concerning the channel access scheme for currently used data transmission systems (such as B3G, 4G, etc.), orthogonal frequency division multiplex (OFDM) is presently favoured to be the most promising access scheme, because it allows a very flexible resource allocation and a low receiver complexity. Having in mind the potential of multi-antennas on the one hand and today's preference of OFDM on the other hand, a combination of both techniques is used. It is assumed that perfect channel state information of the vector channel between the transmit antennas of the access points and the reception antennas of the mobile terminals is available on the transmitting side. In the case of time division duplex (TDD), this knowledge can be readily gained from the uplink channel estimator.

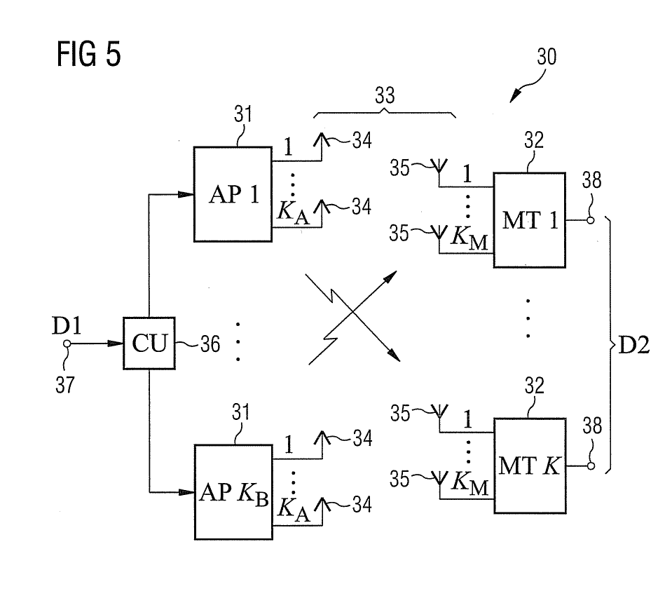

FIG. 5 shows a diagram of a downlink communication 30 of an OFDM data transmission system according to the present invention.

In FIG. 5 the abbreviation CU stands for central unit, AB for access point 31 and MT for mobile terminal 32. These mobile terminals 32 form the receiver or the user equipments, whereas the access points 31 may be the base stations or the corresponding transmitter.

In FIG. 5 there is a single input terminal 37 which is on the input side connected to the central unit 36 at the input terminal 37 input data is provided to the central unit 36. These input data D1 may contain the data block A. The central unit 36 is connected to each one of the access points 31 to provide these access points 36 with the data to be transmitted. Each one of the mobile terminals 32 comprises an output terminal 38. And these output terminals 38 the data estimates D2 are provided from each one of the mobile terminals 32.

There are K_{B} access points which service K_{R} mobile terminals over a noisy vector channel. Each access point is equipped with a number of K_{A} transmit antennas 34, and each mobile terminal 35 comprises K_{M} receive antennas. The K_{B} access points are controlled by a central unit. In the configuration of the downlink in FIG. 5 there are

K_{T}=K_{B}K_{A} (23)

transmit antennas 34 and

K_{R}=KK_{M} (24)

receive antennas 35, with

K_{T}>K_{R}. (25)

It is desired to separately address each of the K_{R} receive antennas 35 by the receiver orientated transmission. Then, to each of the K_{R} receive antennas 35 an independent data stream can be transmitted, with all K_{R} data streams utilizing the same available transmission resources. These transmission resources are e.g. OFDM subcarriers and time. This amounts to a K_{R}-fold augmentation of the spectrum efficiency as compared to a utilizing of only one transmit antenna 34. With the exception of situations with rank deficient vector channels, such an augmentation of spectrum efficiency is feasible by applying the TxZF-method, however, unfortunately with the drawback of a significant overhead of the required transmit energy. This overhead is needed to compensate the multiple access interference between the amount of K_{R} data streams.

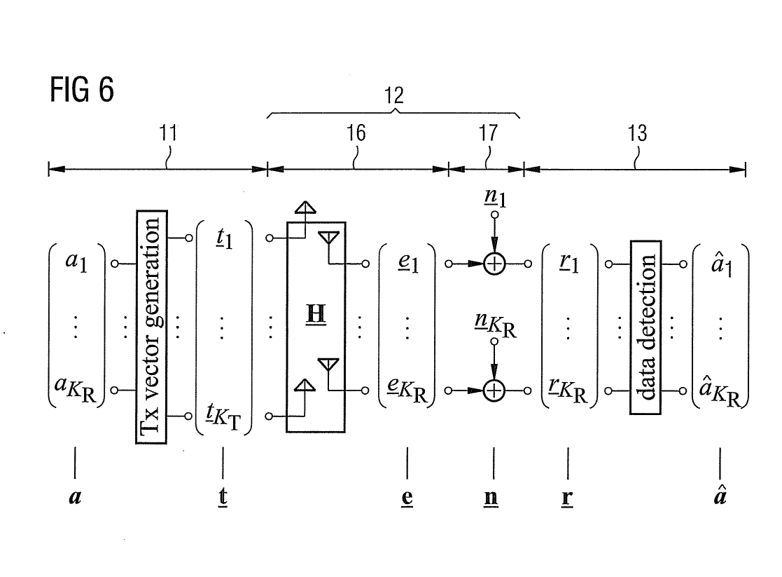

Therefore, according to the present invention, a single OFDM symbol is given and a subcarrier-wise approach is used. Then, the configuration shown in FIG. 5 can be boiled down to the system model of FIG. 6, which only contains what remains after abstracting the self-evident OFDM typical operations of a serial-to-parallel conversion: IFFT in the transmitter, addition of the cyclic prefix within the transmitter, removing the cyclic prefix in the receiver and performing a FFT in the receiver.

The demodulator matrix D can be substituted by a unit matrix, or, equivalently, even omitted. The complex quantities in FIG. 6 represent complex amplitudes or channel transfer function values, respectively, valid for the considered subcarrier.

In the embodiment of FIG. 6 the component t_{kT} of the transmit vector t is fed into the transmit antenna k_{T}. The vector channel is described by the K_{R}K_{T} transfer function values h_{kR,kT} with k_{R}=1 . . . K_{T.}These values constitute the channel matrix

$$\underline{H} = ( \begin{matrix}{\underline{h}}_{1 , 1} & ⋯ & {\underline{h}}_{1 , {K}_{T}} \\ ⋮ & ⋰ & ⋮ \\ {\underline{h}}_{{K}_{R} , 1} & ⋯ & {\underline{h}}_{{K}_{R} , {K}_{T}}\end{matrix} ) ∈ {C}^{{K}_{R} \times {K}_{T}} \qquad ( 26 )$$

of equation (13). Now, with H of equation (26) and with omitting the demodulator matrix D, the MESP method can be performed according to equation (22).

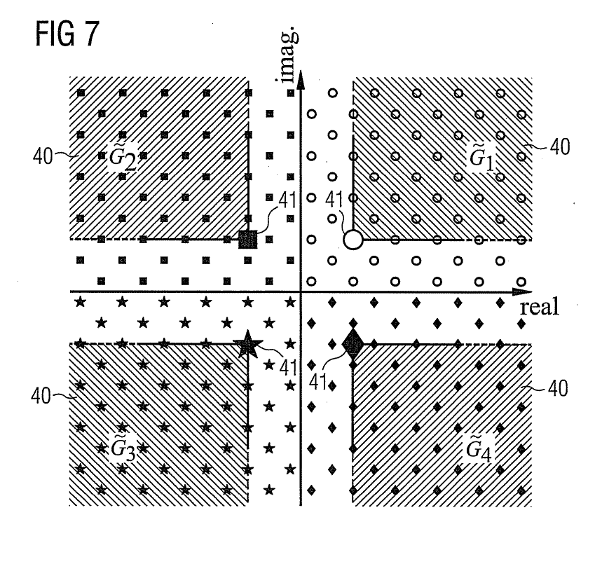

For performing this MESP method the following parameter settings are chosen (see example of FIG. 7):

$$\begin{matrix}M = 4 , & ( 27 ) \\ P = 1 , & ( 28 ) \\ {K}_{T} = {K}_{R} = 4 or 8 , & ( 29 ) \\ {\underline{g}}_{m , p} = {\underline{g}}_{m} = \frac{a}{\sqrt{2}} exp ( j \frac{π}{2} ( m - 0.5 ) ) , m = 1 … 4 , p = 1 , & ( 30 )\end{matrix}$$

The K_{R} components of the noise vector n are assumed to obey independent bivariate Gaussian distributions with the variance σ² of the real and imaginary parts of the components of n. For simplicity further the representative domains 40

$${\tilde{G}}_{m} = \{ {\underline{d}}_{{k}_{R}} ∈ {G}_{m} \vert ( Re ( {\underline{d}}_{{k}_{R}} ) \geq \frac{a}{2} ⋀ Im ( {\underline{d}}_{{k}_{R}} ) \geq \frac{a}{2} ) \} exp ( j \frac{π}{2} ( m - 1 ) ) , \\ m = 1 … 4 , \qquad ( 31 )$$

(see FIG. 7) are chosen, which are confined by straight lines and which, therefore, do not exactly comply with equation (21), since equation (21) would yield representative domains with curved boundaries. Spot landings 41 on the representatives goof equation (30), that are, in the example of FIG. 7, the corner points 41 of the representative domains Gₘ of equation (31), would yield the symbol error probabilities

$${P}_{s , {\underline{g}}_{m}} = {P}_{0 , {a}_{{k}_{R}}} = erfc ( \frac{1}{\sqrt{2}} \cdot \frac{a}{2 σ} ) - {\frac{1}{4} [ erfc ( \frac{1}{\sqrt{2}} \cdot \frac{a}{2 σ} ) ]}^{2} \qquad ( 32 )$$

and landings in any other point of the representative domains Gₘ would advantageously result in smaller symbol error probabilities P_{akR}.

Based on the above given parameter settings and on the basis of a given channel model, a computer simulation was performed for verification of this results. In this simulation many snapshots are used, each comprising:
different positions of the mobile terminals,
different realisations of the channel matrix H of equation (26), and
different realisations of the data block a of equation (1).

In the case of the TxZF- and the MESP-method, for each snap-shot a certain transmit energy T results, and, for a given noise variance σ², a certain symbol error probability Pₛ is obtained. Then E{Pₛ} can be depicted versus the pseudo signal-noise-ratio per user.

$$ϒ = \frac{E \{ T \}}{{K}_{R} \cdot {σ}^{2}} \qquad ( 33 )$$

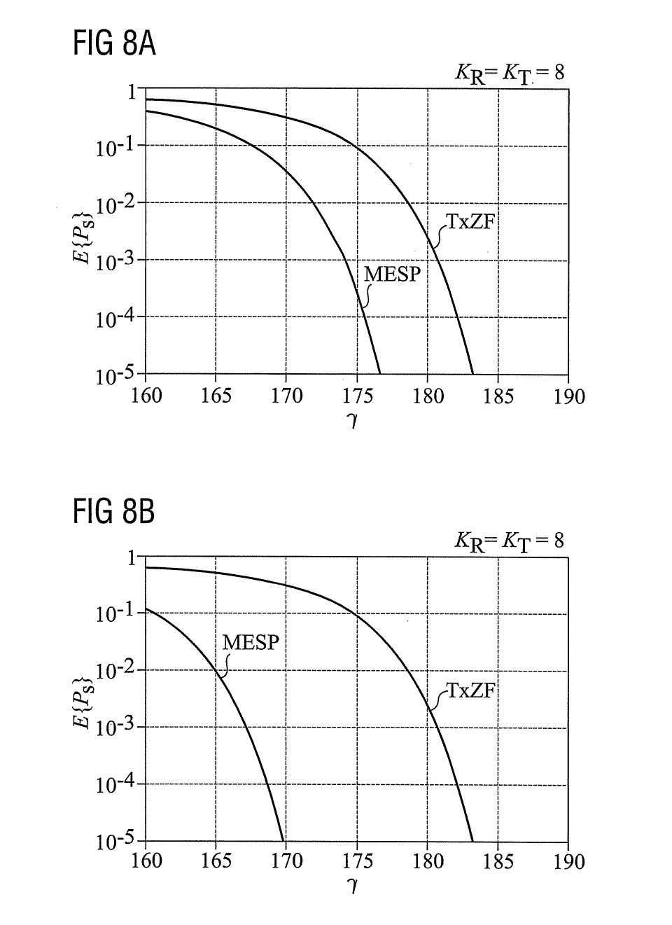

The result of this simulation are curves which characterise the performance of the known TxZF-method and the MESP-method according to the present invention. Examples of these curves are shown in FIG. 8A, 8B.

It has turned out that the new MESP-method according to the present invention shows a significant lower symbol error probability PS than the known TxZF-method.

It is self-understood, that the above-mentioned method of the MESP according to the present invention is only one possible example. However, it is also possible to vary this MESP-method using representative domains instead of spot-landings. Another embodiment of the MESP-method is described hereinafter, whereas this MESP-method is denoted as step-wise approach to MESP.

In the stepwise approach of MESP to be described in what follows the data elements α_{KR} are processed in the order of increasing k_{R}. This ordering does not restrict generality, because any other order could be effected in a straight-forward way by relabeling the elements α_{kR} of α.

Proceeding analogously to the considerations of TₓNZF, each component d_{kR o}f the data vector d can be considered to be the sum of an interference component i_{kR} resulting from the transmission of data elements a′_{kR} with k′_{R}=1 . . . k_{R}−1 and an additional component Δ_{kR} produced specifically for the transmission of a_{kR}, that is

d_{kR}=i_{kR}+ΔkR (34)

If α_{kR} has the realization Gₘ, then Δ_{kR} in equation (34) should be chosen such that, for a given i_{kR}, d_{kR} reaches Gₘ of (20) under the side condition that |Δ_{kR}| is as small as possible. This way to determine Δ_{kR} can be mathematically expressed as

Δ_{kR}=arg{min(|Δ_{kR}|)|a_{kR}=Gₘ},

s. t. i_{kR}+Δ_{kR} εE\tilde{G}ₘ (35)

Now, our stepwise approach of MESP can be described as follows:

For the transmission of the data element akR a data element specific transmit vector t_{kR} is generated, which
produces Δ_{kR} of equation (35),
produces no interference to all components d_{k′R} with k′_{R}=1 . . . k_{R}−1, and
may produce interference to components d_{k′R} with k′_{R}<k_{R}.

In order to mathematically formulate this procedure we set out from the system matrix

B=D H=(b⁽¹⁾^{^{T}} . . . b^{(K}^{_{R}}⁾^{^{T}}⁾^{^{T}} (36)

With the rows b^{(1)T} . . . b^{(kR)T}of the matrix B the partial system matrices

B^{(k}_{is R}⁾=(b⁽¹⁾^{^{T}} . . . b^{(k}^{_{R}}⁾^{^{T}}⁾^{^{T}} (37)

and the vector

m^{(k}^{_{R}}⁾=[(B^{(k}^{_{R}})^{H}(B^{(k}^{_{R}}⁾)(B^{(k}^{_{R}}⁾))⁻¹]column k_{R} (38)

are formed.

This vector yields by multiplication with Δ_{kR} of equation (35) the partial transmit vector

t^{(k}^{_{R}}⁾=m^{(k}^{_{R}}⁾*Δ_{di k}_{_{R}} (39)

for a_{kR}. After having determined all K_{R} partial transmit vectors t^{(k}^{_{R}}⁾ of equation (39), the total transmit vector

$$\underline{t} = {\sum }_{{k}_{R}^{′} = 1}^{{K}_{R}} {\underline{t}}^{( {k}_{R} )} \qquad ( 40 )$$

follows.

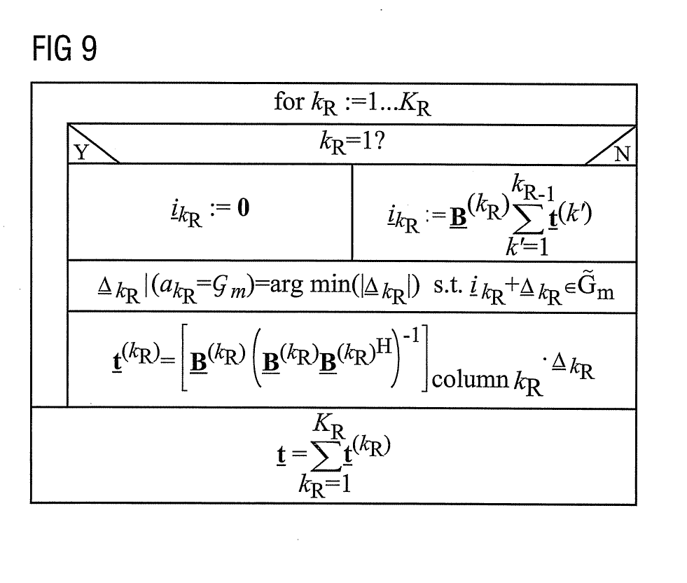

The procedure described above can be concisely represented by the Nassi-Shneiderman diagram shown in FIG. 9.

As the target system for illustrating the stepwise MESP a MIMO OFDM multi-user downlink as described in is chosen. It is assumed that a number of N_{F} subcarriers, K_{T} transmit antennas as and K_{R}=K_{T} mobile terminals are given, each of them equipped with a single antenna. In order to describe the vector channel between the transmit antennas and the mobile terminals, for each subcarrier a channel matrix

$${\underline{H}}^{( {n}_{F} )} = ( \begin{matrix}{\underline{h}}_{1 , 1}^{( {n}_{F} )} & ⋯ & {\underline{h}}_{1 , {K}_{T}}^{( {n}_{F} )} \\ ⋮ & ⋰ & ⋮ \\ {\underline{h}}_{{K}_{R} , 1}^{( {n}_{F} )} & ⋯ & {\underline{h}}_{{K}_{R} , {K}_{T}}^{( {n}_{F} )}\end{matrix} ) ∈ {C}^{{K}_{R} \times {K}_{T}} , {n}_{F} = 1 … {N}_{F} \qquad ( 41 )$$

is introduced. As already shown the demodulator matrix D in FIG. 3 and equation (37) can be substituted by the unit matrix, or, equivalently, it can be also just omitted.

When performing the stepwise MESP according to the present invention, a subcarrier-wise approach is chosen, which yields for each of the N_{F} subcarriers a transmit energy T_{nF}. From these subcarrier specific transmit energies the total transmit energy

$$T = {\sum }_{n F = 1}^{{N}_{F}} {T}_{{n}_{F}} \qquad ( 42 )$$

is obtained.

Before performing the stepwise MESP for a specific subcarrier nF, the order in which the K_{R} mobile terminals are treated has to be determined. Far this purpose for each of the K_{R} mobile terminals the quantity

$${α}_{{k}_{R}}^{( {n}_{F} )} = {\sum }_{{k}_{T} = 1}^{{K}_{T}} {\vert {\underline{h}}_{{k}_{R} , {k}_{T}}^{( {n}_{F} )} \vert}^{2} , \qquad ( 43 )$$

are calculated which are denoted as the channel attenuation of a mobile terminal k_{R} on the subcarrier n_{F}. Then, the mobile terminals are treated in the order of decreasing channel attenuations α_{kR}^{(nF)} of the following equation (44). The order of the mobile terminals resulting in this way may differ from subcarrier to subcarrier.

For the different parameters K_{T}, K_{R}, M, P and N_{F} of the considered downlink as well as for the noise variance σ² per subcarrier the values listed in following table 1 are chosen.

P=0 means that there are simply connected representative domains, which are chosen according to

$${\tilde{G}}_{m} = \{ {\underline{d}}_{{k}_{R}} ∈ C \vert ( Re ( {\underline{d}}_{{k}_{R}} ) \geq \frac{1}{2} ⋀ Im ( {\underline{d}}_{{k}_{R}} ) \geq \frac{1}{2} ) \} exp ( j \frac{π}{2} ( m - 1 ) ) , \\ m = 1 … M \qquad ( 44 )$$

The representative domains Gₘ of equation (4) correspond to the one shown in FIG. 7.

| parameter | value |
|---|---|
| K_{T} = K_{R} | 4 and 8 |
| M | 4 |
| P | 1 |
| N_{F} | 1201 |
| δ² | 0.046 |

In the simulations 100 independent channel snapshots are considered for each of the three channel models (i.e. TxZF, TxNZF, MESP) mentioned above and for each of the 1201 subcarriers, and in each of those snapshots 50 randomly selected data blocks a are transmitted by stepwise MESP. This means that for each of the three channel models 100×50 equal to 5000 transmit energies T of equation (42) can be obtained, which have the average Tₐᵥ.

Also, for each channel snapshot, each subcarrier and each data element of each data block the bit error probability P_{b} can be obtained. Averaging over all these bit error probabilities yields P_{b,av}.

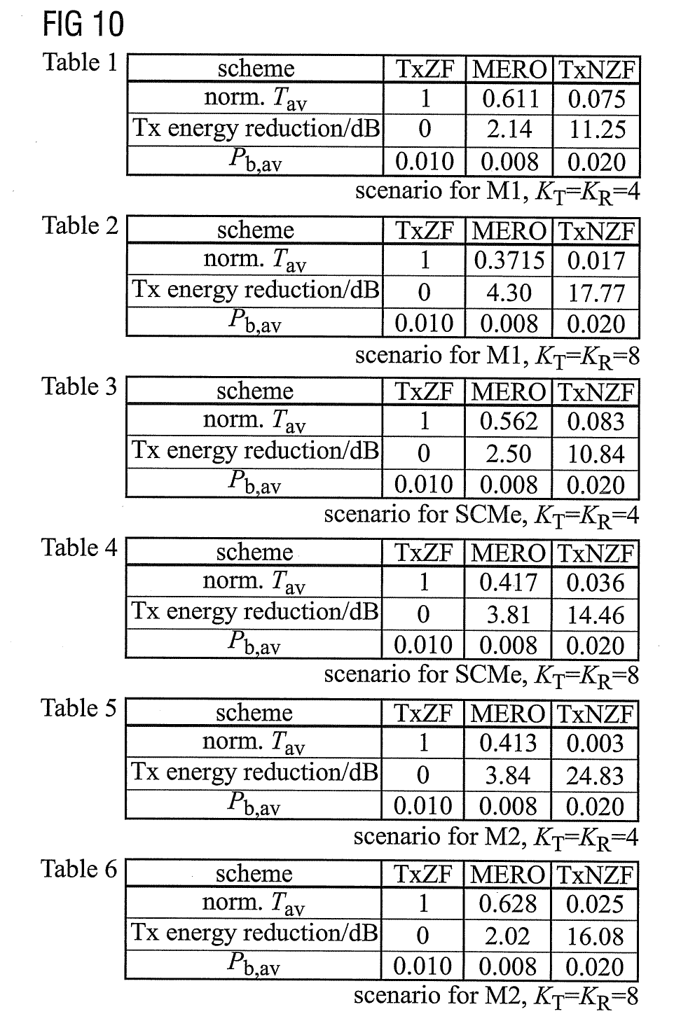

The simulation results are shown in the tables 1-6 of FIG. 10, in which also the TxZF-method and the stepwise TxNZF-method were included for better comparisons of the different performances, the latter one for infinite P.

In these tables 1-6 of FIG. 10 it can be seen:
Tₐᵥ is normalized to the average transmit energy required by TxZF;
The average transmit energy reduction as compared to TxZF;
The average bit error probability P_{b,av}.

The results in the tables 1-6 of FIG. 10 show that, with respect to the required transmit energy Tₐᵥ and P_{b,av,} both stepwise MESP and stepwise TxNZF are superior to the TxZF-method. Energy wise the performance of stepwise MESP is below that of stepwise TxNZF, which is the prize of the reduced complexity of stepwise MESP as compared to stepwise TxNZF. However, with respect to the bit error probability P_{b,av} MESP performs best, both with regard to TxZF and TxNZF.

While embodiments and applications of this invention have been shown and described above, it should be apparent to those skilled in the art, that many more modifications (than mentioned above) are possible without departing from the inventive concept described herein. The invention, therefore, is not restricted except in the spirit of the appending claims.

It is therefore intended that the foregoing detailed description is to be regarded as illustrative rather than limiting and that it is understood that it is the following claims including all equivalents described in these claims that are intended to define the spirit and the scope of this invention. Nor is anything in the foregoing description intended to disavow the scope of the invention as claimed or any equivalents thereof.

It is also noted that the above mentioned embodiments and examples of MESP should be understood to be only exemplary. That means, that additional system arrangements and functional units may be implemented within the base stations (or access points or transmitters) and/or within one or more of the user equipments (or mobile terminals or receivers).

Further, the present invention is explicitly not limited to a wireless communication system but can also be used in a hardwired communication network, which is, for example, also symbol based and/or receiver oriented.

A user equipment is, for example a mobile terminal, especially, a mobile telephone or a mobile or fixed device for transmission of image and/or sound data, for fax services, for short message services (SMS), for multimedia messaging service (MMS) and/or e-mail transmission and/or for internet access.

A base station is a network-side station which is designed to receive the user data and/or signalling data from at least one user equipment and/or is designed to send user data and/or signalling data to the corresponding user equipment. The base station is typically coupled via network-side devices to a core network, via which connections are made to other radio communication systems in other networks.

A data network is typically but not necessarily to be seen as the internet or a fixed network with, for example, circuit-switched or packet-switched connections for noise and/or data signals.

The description describes a base station as a sending station and an user equipment as a receiving station, however, without wishing to express that the invention is to be restricted to this arrangement of a communication system. An user equipment may also be used as a sending station and a base station may also be used as a receiving station, for example.

Data transmission can be both bidirectional between the base station and the user equipment or only unidirectional between one of the base station and the user equipment and the corresponding other one.

The invention can advantageously also be used in any communication system, especially in radio communication systems.

Radio communication systems are especially any mobile radio system, for example in accordance with the commonly known GSM standard or the UMTS standard. Future mobile radio communication systems, for example of the fourth generation, as well as ad hoc networks, are also to be understood as radio communication systems. Radio communication systems are, for example, also WLANs (Wireless Local Area Networks) as well as Bluetooth networks and broadband networks with wireless access.

1. Method for data transmission between at least one transmitter station and at least one receiver station of a communication system, especially a wireless communication system, employing a transmission scheme based on the principle of receiver orientation, wherein for the purpose of selectable data representation the transmit signals comprises the transmit data elements and wherein the transmit data elements are represented by continuous valued representative domains in the complex plane, comprising:
generating the transmit signals within the transmitter station by optimization such that in the receiver stations extended continuous valued landings on the continuous valued representative domains occur.

2. Method according to claim 1,
wherein simply connected representative domains are used.

3. Method according to claim 1,
wherein multiply connected representative domains are used.

4. Method according to claim 1,
wherein the method is used for the generation of low energy transmit signals.

5. Method according to claim 1,
wherein the method is used for the generation of Crest-factor reduced transmit signals.

6. Method according to claim 1,
wherein receiver orientation refers to a transmission scheme where the at least one receiver stations form the master and the at least one transmitter stations form the slave of the data communication.

7. Method according to claim 1,
wherein an receiver algorithm within a receiver station is a priori given and made known to the transmitter station and wherein an transmitter algorithm within a transmitter station is a posteriori adapted accordingly under consideration of given channel state information.

8. Method according to claim 7,
wherein a channel is defined between the at least one transmit antennas of a transmitter station and the at least one reception antennas of a corresponding receiver station, wherein the given channel state information of this channel is obtained within the transmitter station or within the receiver station.

9. Method according to claim 7,
wherein a receiver station estimates channel state information and wherein a corresponding transmitter station obtains the given channel state information by analogue retransmission or by digital retransmission of these estimated channel state information.

10. Method according to claim 7,
wherein a TDD-data transmission is employed in which the frequency in the downlink corresponds to the frequency in the uplink, and wherein the transmitter station obtains the given channel state information by utilizing the reciprocity of the channel and by evaluating the received information.

11. Method according to claim 1,
wherein an extended continuous valued representative domain defines a region around at least one discrete valued representative.

12. Method according to claim 1,
wherein the extended continuous valued representative domain is chosen by optimization such that the symbol error probabilities for landings on the boundaries of this extended continuous valued representative domain attain preset values or attain given values.

13. Method according to claim 1,
wherein for determining the transmit vector at least one of an exhaustive search, a sequential quadratic programming (SQP) or a mixed-integer nonlinear programming method (MINLP) is applied.

14. Method according to claim 1,
wherein the transmit vector is generated in a stepwise process.

15. Method according to claim 14,
wherein the order followed in the stepwise process is chosen depending on channel attenuations.

16. Method according to claim 1,
wherein the method is used in the downlink of the data communication system.

17. Method according to claim 1,
wherein for data transmission Orthogonal Frequency Division Multiplex (OFDM) is applied to send the transmit signal.

18. Method according to claim 1,
wherein for data transmission Code Division Multiple Access (CDMA) is applied to send the transmit signal.

19. Method according to claim 1,
wherein the method is applied to a MIMO communication system and wherein in the MIMO communication system at least one receiver station and/or transmitter station is/are provided which comprise at least multiple receive antennas and transmit antennas, respectively.

20. Method according to claim 1,
wherein the data transmission is symbol-based using at least one data symbol for transmitting the data.

21. Method according to claim 1,
wherein the communication system is a radio communication system and an interface between one transmitter station and at least one corresponding receiver stations is a wireless interface.

22. Method according to claim 1,
wherein the method is applicable for 3G LTE, WIMAX and/or 4G communication systems.

23. Method according to claim 1,
wherein the data elements of the data vector are processed within the transmitter station in the order of increasing k_{R} wherein k_{R} denotes the number of a specific data element of the data vector.

24. Method according to claim 1,
wherein for data transmission a data element specific transmit vector is generated.

25. Method according to claim 24,
wherein the data element specific transmit vector produces no interference to the elements of the complex data response vector.

26. Transmitter station for data transmission using a receiver station of a communication system capable to perform a method according to claim 1.

27. Communication system, especially a radio communication system, comprising at least one transmitter station and at least one receiver station capable to establish a communication with each other via an interface, especially a radio interface, wherein at least one of the transmitter stations is a transmitter station according to claim 26.
